(19) United States
(12) Patent Application Publication
(10) Pub. No.: US 2026/0090364 A1
(43) Pub. Date: Mar. 26, 2026

(54) METHOD OF MANUFACTURING SACRIFICIAL LAYER AND METHOD OF MANUFACTURING SEMICONDUCTOR DEVICE BY USING THE SAME

(71) Applicant: Samsung Electronics Co., Ltd., Suwon-si (KR)

(72) Inventors: Eunchan JEONG, Suwon-si (KR); Eunhyea KO, Suwon-si (KR); Gunjoo PARK, Daejeon-si (KR); Jonghwan PARK, Suwon-si (KR); Seung SON, Daejeon-si (KR); Sunggi KIM, Daejeon-si (KR); Seungmin RYU, Suwon-si (KR); Sanghoon AHN, Suwon-si (KR); Minkyoung LEE, Suwon-si (KR); Youn Joung CHO, Suwon-si (KR); Junhee CHO, Daejeon-si (KR); Hojung CHOI, Suwon-si (KR); Hoon HAN, Suwon-si (KR)

(73) Assignees: Samsung Electronics Co., Ltd., Suwon-si (KR); DNF Co., Ltd., Daejeon (KR)

(21) Appl. No.: 19/252,323

(22) Filed: Jun. 27, 2025

(30) Foreign Application Priority Data
Sep. 20, 2024 (KR) 10-2024-0127536

(51) Int. Cl. H01L 21/768

(52) U.S. Cl. CPC H10W 20/46; H10W 20/072; H10W 20/077; H10W 20/098

(57) ABSTRACT

A method of manufacturing a sacrificial layer may include providing a first compound including an amine compound including at least one secondary amine and a second compound including an isocyanate compound, and forming a sacrificial layer including polyurea through a polymerization reaction of the first compound and the second compound.

### CROSS-REFERENCE TO RELATED APPLICATION

This application is based on and claims priority under 35 U.S.C. § 119 to Korean Patent Application No. 10-2024-0127536, filed on Sep. 20, 2024, in the Korean Intellectual Property Office, the disclosure of which is incorporated by reference herein in its entirety.

### BACKGROUND

Inventive concepts relate to a method of manufacturing a sacrificial layer and/or a method of manufacturing a semiconductor device by using the same, and more particularly, to a method of manufacturing a sacrificial layer for thermal decomposition and/or a method of manufacturing a semiconductor device using the same.

As electronics technology advances, the down-scaling of semiconductor devices may progress rapidly. Accordingly, as the line width and pitch of metal wires included in semiconductor devices are becoming smaller, RC signal delay, crosstalk between the metal wires, and increased power consumption may occur. In particular, as the intervals between the metal wires decrease, parasitic capacitance values may increase rapidly. As a result, focus on the RC signal delay may increase as a design rule shrinks.

Accordingly, there may be a need to develop a process capable of forming an air gap with a relatively low dielectric constant (k) between metal wires so as to reduce a parasitic capacitance between the metal wires.

### SUMMARY

Inventive concepts provide a method of manufacturing a sacrificial layer that is relatively suitable for mass production.

Inventive concepts also provide a method of manufacturing a sacrificial layer having relatively excellent gap-fill characteristics.

Inventive concepts also provide a method of manufacturing a semiconductor device, in which damage to other components is limiting and/or minimized and in which difficulty of a thermal decomposition process is reduced when thermal decomposition is performed through a sacrificial layer having a relatively low thermal decomposition temperature.

Inventive concepts also provide a method of manufacturing a semiconductor device, the reliability of which is improved by reducing leakage current through a sacrificial layer with relatively little residue after thermal decomposition.

In addition, aspects of inventive concepts are not limited to those described above, and other aspects that are not mentioned herein will be clearly understood from the following description by those of ordinary skill in the art.

According to an example embodiment of inventive concepts, a method of manufacturing a sacrificial layer may include providing a first compound and a second compound; and forming a sacrificial layer including polyurea through a polymerization reaction of the first compound and the second compound. The first compound may include an amine compound including at least one secondary amine. The second compound may include an isocyanate compound.

According to an example embodiment of inventive concepts, a method of manufacturing a semiconductor device may include providing a first compound and a second compound on a substrate having a plurality of conductive structures formed thereon, the first compound including an amine compound including at least one secondary amine, and the second compound including an isocyanate compound; forming a sacrificial layer including polyurea between the plurality of conductive structures through a polymerization reaction of the first compound and the second compound; forming a capping layer covering upper surfaces of the plurality of conductive structures and an upper surface of the sacrificial layer; and forming an air gap between the plurality of conductive structures by heating the substrate, on which the capping layer is formed, to thermally decompose the sacrificial layer.

According to an example embodiment of inventive concepts, a method of manufacturing a semiconductor device may include providing a first compound represented by Formula 1 and a second compound represented by Formula 2 on a substrate on which a plurality of conductive structures and a hard mask layer covering upper surfaces of the plurality of conductive structures are formed; forming a sacrificial layer including polyurea between the plurality of conductive structures through a polymerization reaction of the first compound and the second compound; recessing an upper portion of the sacrificial layer by using the hard mask layer as an etch mask; forming a capping layer covering the upper surfaces of the plurality of conductive structures and an upper surface of the sacrificial layer; and thermally decomposing the sacrificial layer by heating the substrate on which the capping layer is formed. In the forming the sacrificial layer, the substrate may be maintained at a temperature of 50° C. to 150° C. In the thermally decomposing the sacrificial layer, the substrate may be maintained at a temperature of about 200° C. to about 400° C.

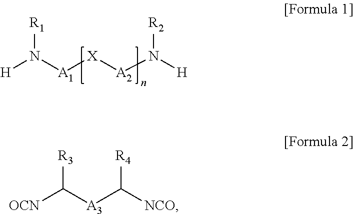

In each of Formulae 1 and 2, A₁ and A₃ each independently may be a C1-C7 alkylene group; A₂ may be a single bond or a C1-C7 alkylene group; X may be O, S, or N—R; R may be a C1-C7 alkyl group; R₁ and R₂ each independently may be a C2-C7 alkyl group; R₃ and R₄ each independently may be hydrogen or a C1-C7 alkyl group; and n may be an integer from 0 to 3.

### BRIEF DESCRIPTION OF THE DRAWINGS

Embodiments will be more clearly understood from the following detailed description taken in conjunction with the accompanying drawings in which:

FIG. 1 is a flowchart for describing a method of manufacturing a sacrificial layer, according to some embodiments;

FIGS. 2A to 2F are cross-sectional views for describing a method of manufacturing a semiconductor device, according to some embodiments;

FIG. 3A is a transmission electron microscopy (TEM) image of a semiconductor device after a sacrificial layer is deposited, according to some embodiments;

FIG. 3B is a TEM image of a semiconductor device after a sacrificial layer is deposited, according to some embodiments;

FIG. 3C is an electron energy loss spectroscopy (EELS) image of a semiconductor device after a sacrificial layer is deposited, according to some embodiments;

FIG. 4 is a TEM image of a semiconductor device after a sacrificial layer is thermally decomposed, according to some embodiments;

FIG. 5A is a TEM image of a semiconductor device after a sacrificial layer is thermally decomposed in a state in which a capping layer is deposited, according to some embodiments; and

FIG. 5B is an EELS image of a semiconductor device after a sacrificial layer is thermally decomposed in a state in which a capping layer is deposited, according to some embodiments.

### DETAILED DESCRIPTION

Embodiments will be described in detail with reference to the accompanying drawings. The same elements in the drawings are denoted by the same reference numerals, and redundant descriptions thereof are omitted.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

The term “amine compound” as used herein is a general term for an amine-containing compound. The amine compound may include a diamine or a triamine and may include a primary amine, a secondary amine, or a tertiary amine. The term “isocyanate compound” as used herein is a generic term for an isocyanate-containing compound. The isocyanate compound may include a diisocyanate or a triisocyanate.

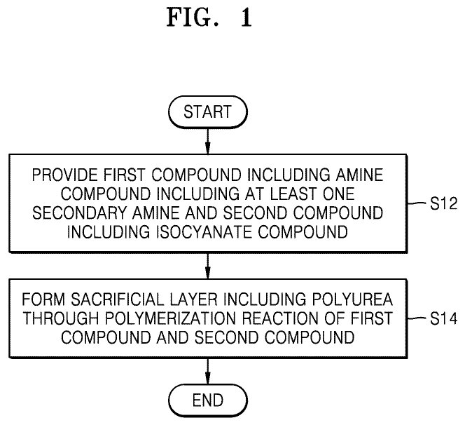

FIG. 1 is a flowchart for describing a method of manufacturing a sacrificial layer, according to some embodiments.

Referring to FIG. 1, operation S12 of providing a first compound including an amine compound including at least one secondary amine and a second compound including an isocyanate compound may be performed.

In embodiments, to deposit the sacrificial layer, each of the first compound and the second compound may be provided on a substrate by chemical vapor deposition (CVD), thermal chemical vapor deposition (TCVD), atomic layer deposition (ALD), or spin coating. In some embodiments, the first compound and the second compound may be simultaneously provided on the substrate.

In embodiments, the first compound may include an amine compound including at least one secondary amine. In some embodiments, the first compound may include a diamine compound.

For example, the first compound may be a diamine compound and one of two amines included in the first compound may be a secondary amine. Examples of the first compound may include N-methylalkylenediamine, N-ethylalkylenediamine, N-propylalkylenediamine, N-isopropylalkylenediamine, N-butylalkylenediamine, N-isobutylalkylenediamine, N-pentylalkylenediamine, N-isopentylalkylenediamine, N-hexylalkylenediamine, and N-peptylalkylenediamine, but this is only an example, and the first compound is not limited to the compounds described above.

For example, the first compound may be a diamine compound and both of the two amines included in the first compound may be a secondary amine. Examples of the first compound may include N,N′-dimethylalkylenediamine, N,N′-diethylalkylenediamine, N,N′-dipropylalkylenediamine, N,N′-dibutylalkylenediamine, N,N′-diisopropylalkylenediamine, N,N′-dipentylalkylenediamine, N,N′-dihexylalkylenediamine, N,N′-diheptylalkylenediamine, and N,N′-diisoheptylalkylenediamine. In addition, examples of the first compound may include one of N,N′-dimethyl-1,6-hexanediamine, N,N′-diethyl-1,6-hexanediamine, N,N′-di-tert-butylethylenediamine, and N,N′-dimethylethylenediamine, but this is only an example, and the first compound is not limited to the compounds described above.

In some embodiments, when the first compound is a diamine compound, the two amines included in the first compound may be different from each other. Examples of the first compound may include N-methyl-alkylene-N′-ethyldiamine or N-methyl-alkylene-N′-propyldiamine. In other embodiments, when the first compound is a diamine compound, the two amines included in the first compound may be identical to each other. Examples of the first compound may include N,N′-diethylalkylenediamine or N,N′-dipropylalkylenediamine.

In some embodiments, the first compound may be a linear compound and may be free of geometric isomers. In other words, the first compound may not be a cyclic compound. Therefore, the quality control of the first compound may be relatively easy, compared to other amine compounds in which geometric isomers exist.

In some embodiments, the first compound may be represented by Formula 1 below:

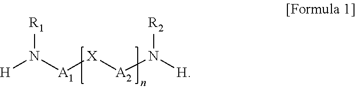

In Formula 1 above, A₁ may be a C1-C7 alkylene group; A₂ may be a single bond or a C1-C7 alkylene group; X may be O, S, or N—R; R may be a C1-C7 alkyl group; R₁ and R₂ may each independently be a C2-C7 alkyl group; and n may be an integer from 0 to 3.

In some embodiments, the first compound may be represented by Formula 1-1 below:

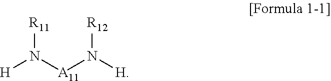

In Formula 1-1 above, Au may be a C1-C7 alkylene group and Ru and R₁₂ may each independently be a C3-C7 alkyl group.

In embodiments, the second compound may include an isocyanate compound. In some embodiments, the second compound may include a diisocyanate compound.

Examples of the second compound may include at least one of 1,2-diisocyanatoethane, 1,4-diisocyanatobutane, 1,5-diisocyanatopentane, or 1,6-diisocyanatohexane. However, this is only an example, and the second compound is not limited to the compounds described above.

In some embodiments, the second compound may be a linear compound and may be free pf geometric isomers. In other words, the second compound may not be a cyclic compound. Therefore, the quality control of the second compound may be relatively easy, compared to other isocyanate compounds in which geometric isomers exist.

In some embodiments, the second compound may be represented by Formula 2 below:

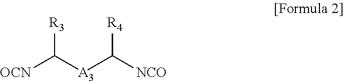

In Formula 2 above, A₃ may be a C1-C7 alkylene group and R₃ and R₄ may each independently be hydrogen or a C1-C7 alkyl group.

Thereafter, operation S14 of forming a sacrificial layer including polyurea through a polymerization reaction of the first compound and the second compound may be performed.

Specifically, the polymerization reaction of the first compound and the second compound may be a reaction in which the amine included in the first compound and the isocyanate included in the second compound are bonded to each other to form a urea bond (—N—CON—). A polyurea, which is a polymer material having a plurality of urea bonds, may be formed through the polymerization reaction of the first compound and the second compound.

In some embodiments, when the first compound is represented by Formula 1 above and the second compound is represented by Formula 2 above, the polymerization reaction of the first compound and the second compound may be represented by Reaction Scheme 1 below:

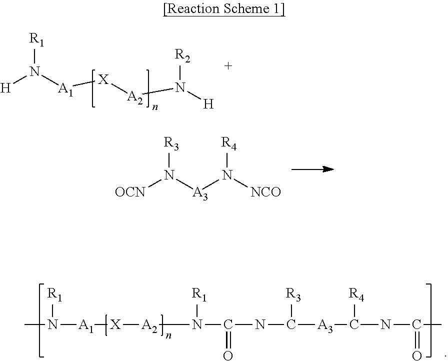

In Reaction Scheme 1 above, A₁ and A₃ may each independently be a C1-C7 alkylene group, A₂ may be a single bond or a C1-C7 alkylene group, X may be O, S, or N—R, R may be a C1-C7 alkyl group, R₁ and R₂ may each independently be a C2-C7 alkyl group, R₃ and R₄ may each independently be hydrogen or a C1-C7 alkyl group, and n may be an integer from 0 to 3.

Referring to Reaction Scheme 1, the nitrogen (N) of the first compound and carbon (C) in a —NCO group of the second compound may be bonded to each other to form a polyurea having a repeating unit including a urea bond (—N—CON—).

In some embodiments, when the first compound is represented by Formula 1-1 above and the second compound is represented by Formula 2 above, the polymerization reaction of the first compound and the second compound may be represented by Reaction Scheme 2 below:

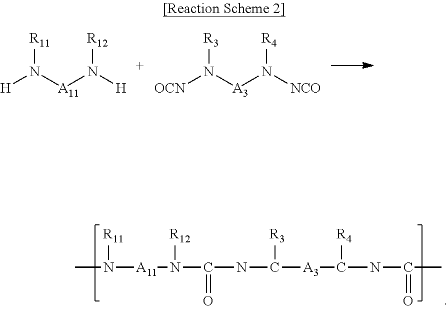

In Reaction Scheme 2, A₁₁ and A₃ may each independently be a C1-C7 alkylene group, R₁₁ and R₁₂ may each independently be a C3-C7 alkyl group, and R₃ and R₄ may each independently be hydrogen or a C1-C7 alkyl group.

Referring to Reaction Scheme 2, as in Reaction Scheme 1, nitrogen (N) of the first compound and carbon (C) in a —NCO group of the second compound may be bonded to each other to form a polyurea having a repeating unit including a urea bond (—N—CON—).

In embodiments, the sacrificial layer including the polyurea may be thermally decomposed at high temperature. The thermal decomposition reaction may include a reaction in which the urea bond (—N—CON—) in the polyurea is decomposed. For example, the sacrificial layer may be thermally decomposed at a temperature of about 50° C. to about 450° C., about 100° C. to about 500° C., about 150° C. to about 550° C., or about 250° C. to about 650° C. Specifically, the sacrificial layer may be thermally decomposed at a temperature of about 200° C. to about 400° C. By-products after the thermal decomposition may include an amine compound and an isocyanate compound.

As a comparative example, when the first compound does not include at least one secondary amine, that is, when the first compound includes only a primary amine, relatively small steric hindrance of the primary amine may allow nitrogen (N) of the urea bond and carbon (C) in the —NCO group of the second compound to be bonded to each other to form additional crosslinking between polyurea chains.

According to embodiments, since the first compound includes at least one secondary amine, relatively large steric hindrance of the secondary amine may reduce or prevent the formation of additional crosslinking between polyurea chains by allowing nitrogen (N) of the urea bond and carbon (C) in the —NCO group of the second compound to be bonded to each other. That is, compared to the comparative example, the polyurea formed according to embodiments may have relatively little crosslinking and a relatively lower bond density.

Therefore, since the sacrificial layer manufactured according to embodiments includes the polyurea having relatively little crosslinking and thus relatively high elasticity, the sacrificial layer may have excellent gap-fill characteristics even between patterns having a relatively narrow critical dimension (CD), compared to the sacrificial layer deposited by using the first compound as the comparative example described above.

In addition, since the sacrificial layer manufactured according to embodiments includes the polyurea having relatively low cross-linking and thus low thermal resistance, the sacrificial layer may be thermally decomposed at a relatively low temperature and the residue after the thermal decomposition may be relatively little, compared to the sacrificial layer deposited by using the first compound as the comparative example described above.

Specifically, as a result of analysis using thermogravimetric analysis (TGA), in each case where the first compound includes the primary diamine compound and the secondary diamine compound, the temperature when the weight is reduced by 50% relative to the weight of the reactant and the ratio of the weight of the residue to the weight of the reactant is shown in Table 1 below. At this time, the weight of the residue was measured at the final temperature of 800° C. by heating the reactant in a temperature increase condition of 10° C./min until the final temperature reached 800° C., and the flow rate of argon (Ar) gas was set to 20 sccm.

Ethylenediamine was used as the primary diamine compound of the first compound and N,N′-di-tert-butylethylenediamine was used as the secondary diamine compound of the first compound. 1,6-diisocyanatohexane was used as the second compound.

TABLE 1

| | Temperature (° C.) when | Residue |
|---|---|---|
| | weight is reduced by 50% | (%) |
| Primary diamine compound | 368 | 7.4 |
| Secondary diamine | 230 | 0.84 |
| compound | | |

Referring to Table 1 above, it may be confirmed that, in a case where the secondary diamine compound is included as the first compound, the temperature when the weight is reduced by 50% relative to the weight of the reactant is significantly reduced to about 230° C., whereas, in a case where the primary diamine compound is included as the first compound, the temperature when the weight is reduced by 50% relative to the weight of the reactant is about 368° C. In addition, it may be confirmed that, in a case where the secondary diamine compound is included as the first compound, the ratio of the weight of the residue to the weight of the reactant is significantly reduced to 0.84%, whereas, in a case where the primary diamine compound is included as the first compound, the ratio of the weight of the residue to the weight of the reactant is 7.4%.

In addition, as a result of analysis using TGA, in each case where a secondary diamine compound including a methyl group, a secondary diamine compound including an ethyl group, and a secondary diamine compound including a t-butyl group were included as the first compound, the temperature when the weight was reduced by 50% relative to the weight of the reactant and the ratio of the weight of the residue to the weight of the reactant are shown in Table 2 below. At this time, as described above, the weight of the residue was measured at the final temperature of 800° C. by heating the reactant in a temperature increase condition of 10° C./min until the final temperature reached 800° C., and the flow rate of argon (Ar) gas was set to 20 seem.

As the first compound, N,N′-dimethylethylenediamine and N,N′-dimethyl-1,6-hexanediamine were used as the secondary diamine compound including the methyl group, N,N′-diethyl-1,6-hexanediamine was used as the secondary diamine compound including the ethyl group, and N,N′-di-tert-butylethylenediamine was used as the secondary diamine compound including the t-butyl group. 1,6-diisocyanatohexane was used as the second compound.

TABLE 2

| | Temperature (° C.) when | Residue |
|---|---|---|
| | weight is reduced by 50% | (%) |
| N,N′-dimethylethylenediamine | 356 | 3.22 |
| N,N′-dimethyl-1,6-hexanediamine | 362 | 2.37 |
| N,N′-diethyl-1,6-hexanediamine | 342 | 1.65 |
| N,N′-di-tert-butylethylenediamine | 230 | 0.84 |

Referring to Table 2 above, it may be confirmed that, when the secondary diamine compound including the methyl group was used as the first compound, the temperature when the weight was reduced by 50% was about 356° C. to 362° C., whereas when the secondary diamine compound including the ethyl group was used as the first compound, the temperature when the weight was reduced by 50% was about 342° C., which was relatively low. In addition, it may be confirmed that, when the secondary diamine compound including the t-butyl group was used, the temperature when the weight was reduced by 50% was about 230° C., which was significantly low. In addition, it may be confirmed that, when the secondary diamine compound including the methyl group was used as the first compound, the ratio of the weight of the residue to the weight of the reactant is about 2.37% to 3.22%, whereas, when the secondary diamine compound including the ethyl group was used as the first compound, the ratio of the weight of the residue to the weight of the reactant was 1.65%, which was relatively low. In addition, it may be confirmed that, when the secondary diamine compound including the t-butyl group was used as the first compound, the ratio of the weight of the residue to the weight of the reactant was about 0.84, which was relatively low.

Therefore, it may be inferred that the thermal decomposition temperature of the sacrificial layer will be relatively low and the residue remaining after the thermal decomposition of the sacrificial layer will be relatively little as the functional group bonded to the secondary amine is a stereoscopically bulky functional group.

Hereinafter, the sacrificial layers according to Examples are described in detail through Experimental Examples. However, the following Experimental Examples are intended to explain the thermal decomposition characteristics of the sacrificial layers according to Examples and are not intended to limit the scope of inventive concepts.

### Example 1

In Experimental Examples below, a sacrificial layer was deposited by CVD, N,N′-di-tert-butylethylenediamine was used as a first compound that is a precursor, and 1,6-diisocyanatohexane was used as a second compound. On a silicon substrate, the first compound was filled into a bubbler-type canister made of stainless steel at 41° C. and a pressure of 1.9 torr, and the second compound was filled at a temperature of 70° C. and a pressure of 0.77 torr. The first compound and the second compound were transferred into a reaction chamber by using argon (Ar) gas as a transfer gas and then provided on the silicon substrate to form a sacrificial layer on the silicon substrate.

To find appropriate conditions required for sacrificial layer deposition, a plurality of experiments were conducted by varying the temperature of the silicon substrate and the deposition time on the silicon substrate. In each Experimental Example, the temperature of the silicon substrate and the deposition time on the silicon substrate are as shown in Table 3-1 below.

TABLE 3-1

| | Temperature (° C.) of | Deposition time |
|---|---|---|
| | silicon substrate | (second) |
| Experimental | 80 | 150 |
| Example 1 | | |
| Experimental | 100 | 150 |
| Example 2 | | |
| Experimental | 80 | 210 |
| Example 3 | | |
| Experimental | 100 | 210 |
| Example 4 | | |
| Experimental | 80 | 270 |
| Example 5 | | |
| Experimental | 100 | 270 |
| Example 6 | | |
| Experimental | 80 | 330 |
| Example 7 | | |

In each Experimental Example, results of measuring a thickness (Å) and a contact angle (°) of the formed sacrificial layer are shown in Table 4-1 below. The contact angle was measured by using a water contact angle meter (Phoenix 300 touch, SEO).

TABLE 4-1

| | Thickness (Å) | Contact angle (°) |
|---|---|---|
| Experimental | 84 | Not measured |
| Example 1 | | |
| Experimental | 29 | Not measured |
| Example 2 | | |
| Experimental | 87 | Not measured |
| Example 3 | | |
| Experimental | 33 | Not measured |
| Example 4 | | |
| Experimental | 123 | 64 |
| Example 5 | | |
| Experimental | 34 | 62 |
| Example 6 | | |
| Experimental | 167 | Not measured |
| Example 7 | | |

Referring to Table 4-1 above, it may be confirmed from the result of measuring the contact angle in Experimental Examples 5 and 6 that a polymer thin-film was formed. Therefore, a substrate temperature suitable for forming the sacrificial layer may be about 80° C. to about 100° C. and a suitable deposition time may be about 270 seconds to about 330 seconds.

Regarding Experimental Example 5 among Experimental Examples, the sacrificial layer was thermally decomposed by varying the temperature of the silicon substrate, and then, the thickness of the sacrificial layer was measured. Results obtained therefrom are shown in Table 5-1 below. A process pressure was 5 torr and a time required for the thermal decomposition was 900 seconds.

TABLE 5-1

| | Temperature (° C.) of | Thickness (Å) after thermal |
|---|---|---|
| | silicon substrate | decomposition |
| Experimental | 200 | 12 |
| Example 5-1 | | |
| Experimental | 300 | 11 |
| Example 5-2 | | |
| Experimental | 400 | 12 |
| Example 5-3 | | |

Referring to Table 5-1 above, it may be confirmed that the thickness of the sacrificial layer in Experimental Example 5-1 is reduced by about 111 Å, that is, from about 123 Å before the thermal decomposition to about 12 Å after the thermal decomposition at 200° C. It may be confirmed that the thickness of the sacrificial layer in Experimental Example 5-2 is reduced by about 112 Å, that is, from about 123 Å before the thermal decomposition to about 11 Å after the thermal decomposition at 300° C. It may be confirmed that the thickness of the sacrificial layer in Experimental Example 5-3 is reduced by about 111 Å, that is, from about 123 Å before the thermal decomposition to about 12 Å after the thermal decomposition at 400° C. Therefore, it may be confirmed that, when the temperature of the silicon substrate is about 200° C. to about 400° C., a portion corresponding to about 90% to about 95% of the sacrificial layer is thermally decomposed.

### Example 2

As in Example 1, a sacrificial layer was deposited by CVD, but N,N′-dimethyl-1,6-hexanediamine was used as a first compound that is a precursor, and 1,6-diisocyanatohexane was used as a second compound. On a silicon substrate, the first compound was filled into a bubbler-type canister made of stainless steel at 60° C. and a pressure of 1.9 torr, and the second compound was filled at a temperature of 70° C. and a pressure of 0.77 torr. The first compound and the second compound were transferred into a reaction chamber by using argon (Ar) gas as a transfer gas and then provided on the silicon substrate to form a sacrificial layer on the silicon substrate.

In each Experimental Example, the temperature of the silicon substrate and the deposition time on the silicon substrate are as shown in Table 3-2 below.

TABLE 3-2

| | Temperature (° C.) | Deposition time |
|---|---|---|
| | of silicon substrate | (second) |
| Experimental | 80 | 120 |
| Example 8 | | |
| Experimental | 100 | 120 |
| Example 9 | | |

In each Experimental Example, results of measuring the thickness of the formed sacrificial layer are shown in Table 4-2 below. Similarly, the contact angle was measured by using a water contact angle meter (Phoenix 300 touch, SEO).

TABLE 4-2

| | Thickness (Å) | Contact angle (°) |
|---|---|---|
| Experimental | 82 | 61 |
| Example 8 | | |
| Experimental | 48 | 57 |
| Example 9 | | |

Regarding Experimental Example 8 among Experimental Examples, the sacrificial layer was thermally decomposed by varying the temperature of the silicon substrate, and then, the thickness of the sacrificial layer was measured. Results obtained therefrom are shown in Table 5-2 below. A process pressure was 5 torr and a time required for the thermal decomposition was 900 seconds.

TABLE 5-2

| | Temperature (° C.) of | Thickness (Å) after |
|---|---|---|
| | silicon substrate | thermal decomposition |
| Experimental | 200 | 16 |
| Example 8-1 | | |
| Experimental | 300 | 11 |
| Example 8-2 | | |
| Experimental | 400 | 10 |
| Example 8-3 | | |

Referring to Table 5-2 above, it may be confirmed that the thickness of the sacrificial layer in Experimental Example 8-1 is reduced by about 66 Å, that is, from about 82 Å before the thermal decomposition to about 16 Å after the thermal decomposition at 200° C. It may be confirmed that the thickness of the sacrificial layer in Experimental Example 8-2 is reduced by about 71 Å, that is, from about 82 Å before the thermal decomposition to about 11 Å after the thermal decomposition at 300° C. It may be confirmed that the thickness of the sacrificial layer in Experimental Example 8-3 is reduced by about 72 Å, that is, from about 82 Å before the thermal decomposition to about 10 Å after the thermal decomposition at 400° C. Therefore, it may be confirmed that, when the temperature of the silicon substrate is about 200° C., a portion corresponding to about 80% of the sacrificial layer is thermally decomposed, and when the temperature of the silicon substrate is about 300° C. to about 400° C., a portion corresponding to about 85% to about 90% of the sacrificial layer is thermally decomposed.

Referring to both Tables 5-1 and 5-2 above, it may be confirmed that, in Example 1 in which the secondary diamine compound of the first compound includes the tert-butyl group, most of the sacrificial layer is removed even though the thermal decomposition temperature of the sacrificial layer is relatively low, compared to Example 2 in which the secondary diamine compound of the first compound includes the methyl group. Therefore, it may be inferred that the thermal decomposition temperature of the sacrificial layer will be relatively low and the residue remaining after the thermal decomposition of the sacrificial layer will be relatively little as the functional group bonded to the secondary amine is a three-dimensionally bulky functional group.

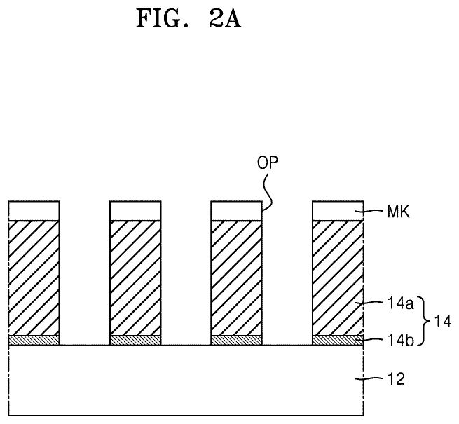

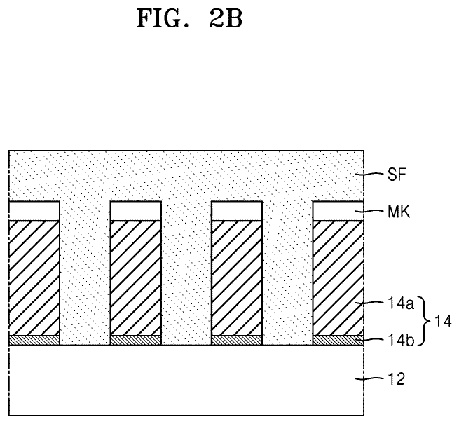

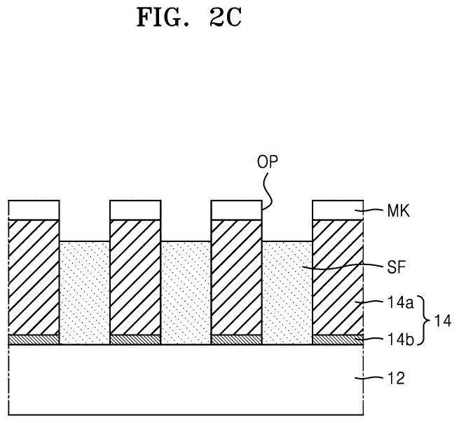

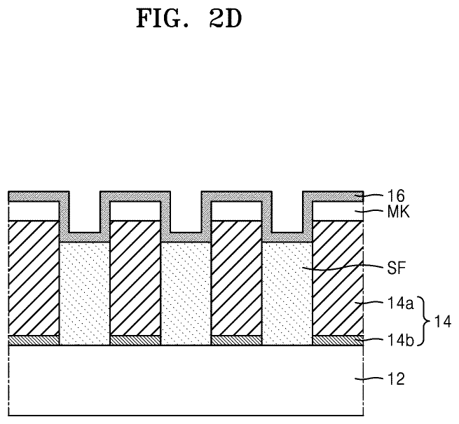

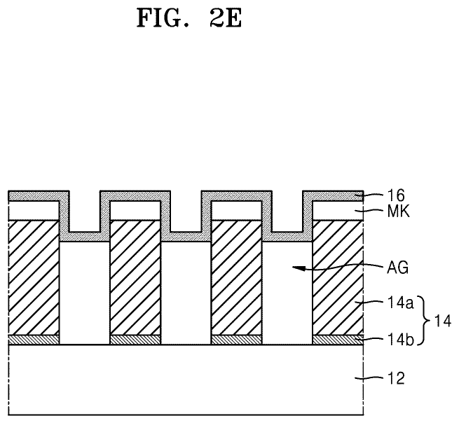

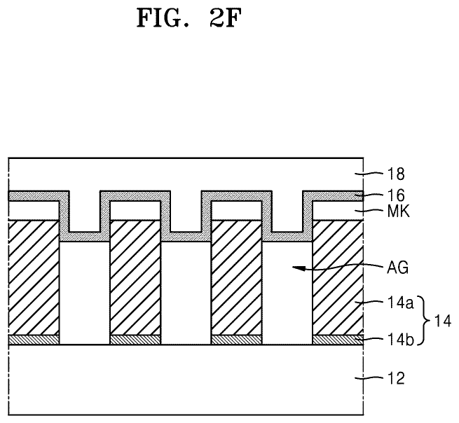

FIGS. 2A to 2F are cross-sectional views for describing a method of manufacturing a semiconductor device, according to some embodiments.

Referring to FIG. 2A, a substrate 12 may be provided. In embodiments, the substrate 12 may include silicon, such as monocrystalline silicon, polycrystalline silicon, or amorphous silicon, or may include at least one selected from Ge, SiGe, SiC, GaAs, InAs, and InP. For example, the substrate 12 may include a conductive area, for example, an impurity-doped well or an impurity-doped structure. In addition, the substrate 12 may have various device isolation structures, such as a shallow trench isolation (STI) structure.

Thereafter, a plurality of conductive structures 14 electrically connected to the conductive area of the substrate 12 may be formed on the substrate 12. In some embodiments, the plurality of conductive structures 14 may have a multilayer structure. For example, the plurality of conductive structures 14 may include a plurality of conductive patterns 14a and a plurality of conductive barrier patterns 14b between the substrate 12 and the plurality of conductive patterns 14a. In some embodiments, the plurality of conductive structures 14 may have a single layer structure. For example, in the structure illustrated in FIG. 2A, the plurality of conductive barrier patterns 14b may be omitted and the plurality of conductive structures 14 may include only the plurality of conductive patterns 14a.

In embodiments, the plurality of conductive patterns 14a may include molybdenum (Mo), copper (Cu), tungsten (W), cobalt (Co), ruthenium (Ru), manganese (Mn), titanium (Ti), tantalum (Ta), aluminum (Al), any combination thereof, or any alloy thereof. In embodiments, the plurality of conductive barrier patterns 14b may include metal or metal nitride. For example, the plurality of conductive barrier patterns 14b may include Ti, Ta, W, TiN, TaN, WN, WCN, TiSiN, TaSiN, WSiN, or any combination thereof, but inventive concepts are not limited thereto.

To form the plurality of conductive patterns 14a, a conductive layer (not shown) may be deposited on the substrate 12, and then, a mask pattern (not shown) including a plurality of openings may be positioned on the conductive layer. The plurality of conductive patterns 14a may be formed by etching a portion of the conductive layer through the plurality of openings. For example, the conductive layer may be deposited by low pressure CVD (LPCVD), plasma enhanced CVD (PECVD), ultra-high vacuum (UHV)-CVD, atomic layer deposition (ALD), metal organic CVD (MOCVD), metal organic ALD (MOALD), etc.

To form the plurality of conductive barrier patterns 14b, a conductive barrier layer (not shown) may be deposited on the substrate 12, and then, a mask pattern (not shown) including a plurality of openings may be positioned on the conductive barrier layer. The plurality of conductive barrier patterns 14b may be formed by etching a portion of the conductive barrier layer through the plurality of openings. For example, the conductive barrier layer may be deposited by LPCVD, PECVD, UHV-CVD, ALD, MOCVD, MOALD, etc.

In some embodiments, the horizontal interval between the plurality of conductive patterns 14a and the plurality of conductive barrier patterns 14b may be about 0.001 nm to about 15 nm. For example, the horizontal interval between the plurality of conductive patterns 14a and the plurality of conductive barrier patterns 14b may be about 1 nm to about 10 nm.

Thereafter, a hard mask layer MK including a plurality of openings OP may be formed on the plurality of conductive structures 14. The hard mask layer MK may cover the upper surfaces of the plurality of conductive structures 14, and the plurality of openings OP of the hard mask layer MK may expose some areas of the upper surface of the substrate 12 between the plurality of conductive structures 14.

In embodiments, the hard mask layer MK may include a material having an etch selectivity with respect to a sacrificial layer SF to be subsequently deposited. For example, the hard mask layer MK may include a silicon oxide layer, a silicon nitride layer, or any combination thereof.

Referring to FIG. 2B, on the resultant structure of FIG. 2A, a first compound including an amine compound including at least one secondary amine and a second compound including an isocyanate compound may be provided on the surfaces of the plurality of conductive structures 14, the surface of the hard mask layer MK, and the exposed surfaces of the substrate 12. Since the first compound and the second compound have been described in detail with reference to FIG. 1, a detailed description thereof is omitted.

In embodiments, the first compound and the second compound may be provided by CVD, thermal CVD (TCVD), ALD, or spin coating.

The first compound and the second compound may form the sacrificial layer SF including polyurea through a polymerization reaction. In embodiments, the sacrificial layer SF may cover the surfaces of the plurality of conductive structures 14, the surface of the hard mask layer MK, and the exposed surfaces of the substrate 12. In the process of forming the sacrificial layer SF, the temperature of the substrate 12 may be maintained at about 50° C. to about 150° C. Since the process of forming the sacrificial layer SF including the polyurea through the polymerization reaction of the first compound and the second compound has been described in detail with reference to FIG. 1, a detailed description thereof is omitted.

Referring to FIG. 2C, in the resultant structure of FIG. 2B in which the sacrificial layer SF is formed, the upper portion of the sacrificial layer SF may be recessed by using the hard mask layer MK as an etch mask. The recess process may be performed by plasma etching (PE). For example, the recess process may be performed by PE using hydrogen (H₂) gas. Through the recess process, some areas of the sacrificial layer SF between the plurality of conductive structures 14 may remain. After the recess process, the vertical level of the upper surface of the sacrificial layer SF may be equal to or lower than the vertical level of the upper surfaces of the plurality of conductive structures 14.

Referring to FIG. 2D, a capping layer 16 may be deposited on the resultant structure of FIG. 2C to cover the surface of the hard mask layer MK, the surfaces of the plurality of conductive structures 14, and the surface of the sacrificial layer SF. In some embodiments, the capping layer 16 may be formed as a layer that conformally extends along the surfaces of the plurality of conductive structures 14 and the surface of the sacrificial layer SF. In some embodiments, the capping layer 16 may be formed as a layer that covers the surfaces of the plurality of conductive structures 14 and the surface of the sacrificial layer SF, but does not extend conformally. For example, the capping layer 16 may have a curved surface.

In embodiments, the capping layer 16 may include a low-density layer that allows the material formed by removing the sacrificial layer SF to pass therethrough. In some embodiments, the capping layer 16 may include a porous layer. For example, the capping layer 16 may include a silicon oxide layer or a silicon nitride layer. Since the capping layer 16 includes a porous layer, the gaseous amine compound and the gaseous isocyanate compound, which are formed when the sacrificial layer SF is removed, may escape through the capping layer 16 in a subsequent process.

Referring to FIG. 2E, the sacrificial layer (see SF of FIG. 2D) may be removed from the resultant structure of FIG. 2D. In some embodiments, the sacrificial layer SF may be thermally decomposed by heating the resultant structure of FIG. 2D, and thus, the sacrificial layer SF may be removed. The urea bond of the polyurea included in the sacrificial layer SF may be decomposed to form a gaseous amine compound and a gaseous isocyanate compound. The gaseous amine compound and the gaseous isocyanate compound may escape through the capping layer 16. In the process of thermally decomposing the sacrificial layer SF, the temperature of the substrate 12 may be maintained at about 200° C. to about 400° C. Since the thermal decomposition of the sacrificial layer SF has been described in detail with reference to FIG. 1, a detailed description thereof is omitted. However, this is only an example, and the sacrificial layer SF may be removed through various processes as well as the thermal decomposition. For example, the sacrificial layer SF may be removed by PE or the like. For example, the sacrificial layer SF may be removed by using hydrogen plasma (hydrogen radicals) or oxygen plasma (oxygen radicals). In addition, after the sacrificial layer SF is partially removed by the thermal decomposition process, the remaining residue may be removed by PE.

The sacrificial layer SF may be removed to form an air gap AG between the plurality of conductive structures 14. The term “air gap” as used herein may be understood as including any cavity filled with substantially inert gas or gaseous materials (including, but not limited to, air). In embodiments, the air gap AG may be defined as a space surrounded by the substrate 12, the plurality of conductive structures 14, and the capping layer 16. The air gap AG may have a dielectric constant (k) of about 1.

Referring to FIG. 2F, for example, an insulating layer 18 may be deposited on the resultant structure of FIG. 2E as a layer for a subsequent process. The insulating layer 18 may include an oxide layer, a nitride layer, an ultra low-k (ULK) layer having a ULK of about 2.2 to about 2.4, or any combination thereof. For example, the insulating layer 18 may include a tetraethylorthosilicate (TEOS) layer, a high density plasma (HDP) oxide layer, a boro-phospho-silicate glass (BPSG) layer, a flowable CVD (FCVD) oxide layer, a SiON layer, a SiN layer, a SiOC layer, a SiCOH layer, or any combination thereof.

In addition, according to the method of manufacturing a semiconductor device, according to embodiments, since the sacrificial layer includes a polymer having relatively little crosslinking and thus low thermal resistance, the thermal decomposition temperature of the sacrificial layer is relatively low. Accordingly, a method of manufacturing a semiconductor device, in which damage to other components is minimized during thermal decomposition and the difficulty of the thermal decomposition process is reduced, may be provided.

Furthermore, according to the method of manufacturing a semiconductor device, according to embodiments, the residue after removal of the sacrificial layer may be relatively little. Accordingly, a method of manufacturing a semiconductor device, in which reliability is improved by reducing leakage current due to the residue, may be provided.

Hereinafter, the gap fill performance and thermal decomposition characteristics of the sacrificial layer is described with reference to transmission electron microscopy (TEM) images and electron energy loss spectroscopy (EELS) images of the semiconductor device according to embodiments.

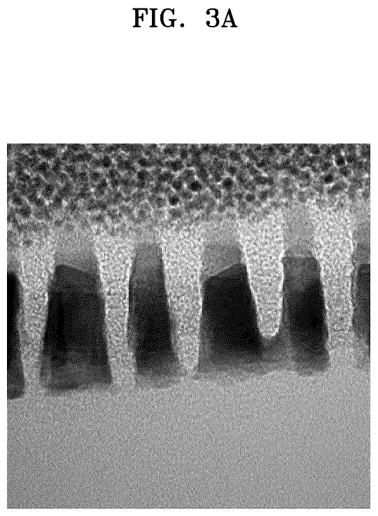

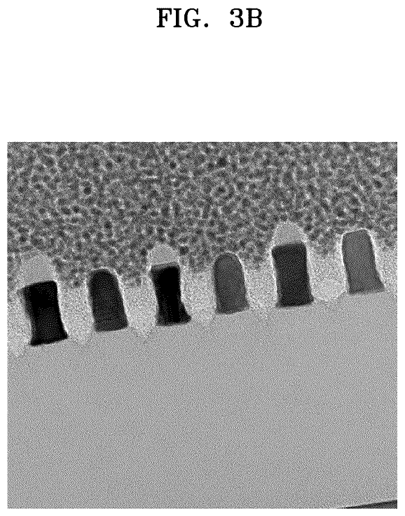

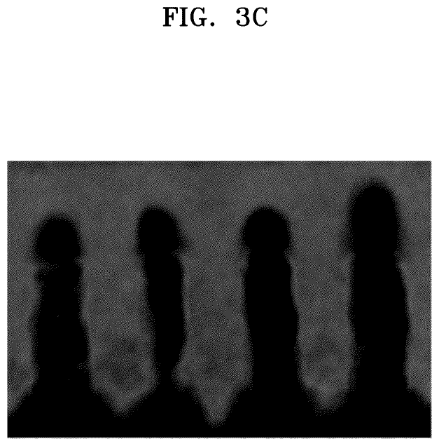

FIG. 3A is a TEM image of a semiconductor device after a sacrificial layer is deposited, according to some embodiments. FIG. 3B is a TEM image of a semiconductor device after a sacrificial layer is deposited, according to some embodiments. FIG. 3C is an EELS image of a semiconductor device after a sacrificial layer is deposited, according to some embodiments.

Specifically, FIG. 3A is a TEM image of a semiconductor device in which a sacrificial layer is coated by depositing N,N′-di-tert-butylethylenediamine as the first compound and 1,6-diisocyanatohexane as the second compound at a temperature of about 80° C. and a pressure of about 5 torr for about 210 seconds, FIG. 3B is a TEM image of a semiconductor device in which a sacrificial layer is coated by depositing N,N′-di-tert-butylethylenediamine as the first compound and 1,6-diisocyanatohexane as the second compound at a temperature of 80° C. and a pressure of about 5 torr for about 150 seconds, and FIG. 3C is an EELS image of a semiconductor device in which a sacrificial layer is coated by depositing N,N′-di-tert-butylethylenediamine as the first compound and 1,6-diisocyanatohexane as the second compound at a temperature of 80° C. and a pressure of about 5 torr.

Referring to FIGS. 3A, 3B, and 3C, it may be confirmed that the sacrificial layer according to embodiments is deposited relatively homogeneously without cavities or voids even when the interval between the plurality of conductive structures is as relatively narrow as about 6 nm to about 10 nm.

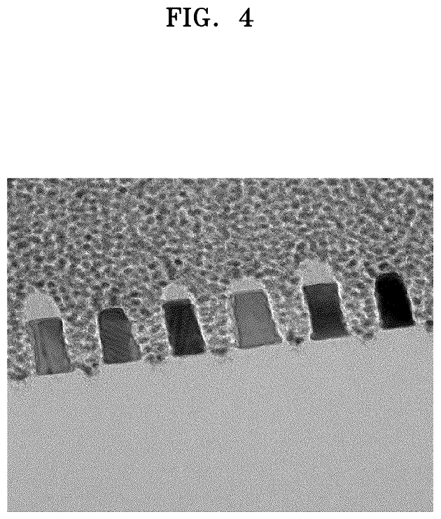

FIG. 4 is a TEM image of a semiconductor device after a sacrificial layer is thermally decomposed, according to some embodiments.

FIG. 4 is a TEM image of a sacrificial layer deposited by using N,N′-di-tert-butylethylenediamine as the first compound and 1,6-diisocyanatohexane as the second compound and then thermally decomposed at a temperature of about 200° C. and a pressure of about 5 torr for about 900 seconds.

Referring to FIG. 4, it may be confirmed that a sacrificial layer deposited by using N,N′-di-tert-butylethylenediamine as the first compound and 1,6-diisocyanatohexane as the second compound leaves relatively little residue after thermal decomposition at a high temperature.

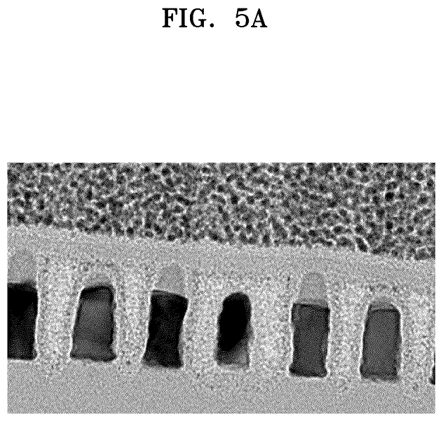

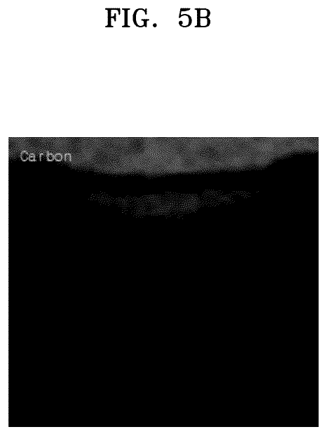

FIG. 5A is a TEM image of a semiconductor device after a sacrificial layer is thermally decomposed in a state in which a capping layer is deposited, according to some embodiments.

FIG. 5B is an EELS image of a semiconductor device after a sacrificial layer is thermally decomposed in a state in which a capping layer is deposited, according to some embodiments.

Specifically, FIG. 5A is a TEM image of a sacrificial layer deposited by using N,N′-di-tert-butylethylenediamine as the first compound and 1,6-diisocyanatohexane as the second compound and then thermally decomposed at a temperature of 300° C. and a pressure of about 5 torr for about 900 seconds. FIG. 5B is an EELS image obtained after a sacrificial layer is thermally decomposed in the same experimental conditions as in FIG. 5A.

Referring to FIGS. 5A and 5B, it may be confirmed that, even when a capping layer is deposited, the thermal decomposition of the sacrificial layer is easily performed and almost no residue remains.

While inventive concepts have been particularly shown and described with reference to embodiments thereof, it will be understood that various changes in form and details may be made therein without departing from the spirit and scope of the following claims.

What is claimed is:

1. A method of manufacturing a sacrificial layer, the method comprising:
providing a first compound and a second compound, the first compound comprising an amine compound including at least one secondary amine, and the second compound including an isocyanate compound; and
forming a sacrificial layer comprising polyurea through a polymerization reaction of the first compound and the second compound.

2. The method of claim 1, wherein the sacrificial layer is thermally decomposed at a temperature of 50° C. to 450° C.

3. The method of claim 1, wherein the first compound has a linear structure.

4. The method of claim 1, wherein the first compound comprises a diamine compound.

5. The method of claim 4, wherein the diamine compound comprises one secondary amine.

6. The method of claim 4, wherein the diamine compound comprises two secondary amines.

7. The method of claim 1, wherein the first compound is represented by Formula 1: 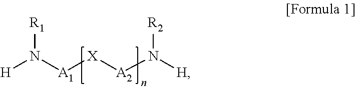
wherein, in Formula 1,
A₁ is a C1-C7 alkylene group,
A₂ is a single bond or a C1-C7 alkylene group,
X is O, S, or N—R,
R is a C1-C7 alkyl group,
R₁ and R₂ are each independently a C2-C7 alkyl group, and
n is an integer from 0 to 3.

8. The method of claim 1, wherein the first compound is represented by Formula 1-1: 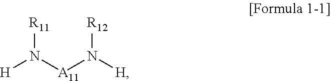
wherein, in Formula 1-1,
A₁₁ is a C1-C7 alkylene group, and
R₁₁ and R₁₂ are each independently a C3-C7 alkyl group.

9. The method of claim 1, wherein the second compound is represented by Formula 2: 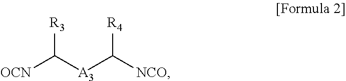
wherein, in Formula 2,
A₃ is a C1-C7 alkylene group, and
R₃ and R₄ are each independently hydrogen or a C1-C7 alkyl group.

10. The method of claim 1, wherein the second compound comprises at least one of 1,2-diisocyanatoethane, 1,4-diisocyanatobutane, 1,5-diisocyanatopentane, or 1,6-diisocyanatohexane.

11. A method of manufacturing a semiconductor device, the method comprising:
providing a first compound and a second compound on a substrate having a plurality of conductive structures formed thereon, the first compound comprising an amine compound including at least one secondary amine, and the second compound including an isocyanate compound;
forming a sacrificial layer comprising polyurea between the plurality of conductive structures through a polymerization reaction of the first compound and the second compound;
forming a capping layer covering upper surfaces of the plurality of conductive structures and an upper surface of the sacrificial layer; and
forming an air gap between the plurality of conductive structures by heating the substrate, on which the capping layer is formed, to thermally decompose the sacrificial layer.

12. The method of claim 11, wherein
the first compound comprises a diamine compound, and
the second compound comprises a diisocyanate compound.

13. The method of claim 11, wherein
the first compound is represented by Formula 1, and
the second compound is represented by Formula 2, 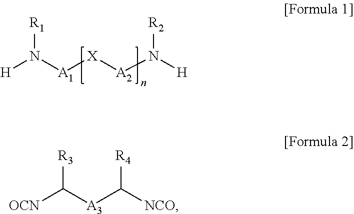
wherein, in each of Formulae 1 and 2,
A₁ and A₃ are each independently a C1-C7 alkylene group,
A₂ is a single bond or a C1-C7 alkylene group,
X is O, S, or N—R,
R is a C1-C7 alkyl group,
R₁ and R₂ are each independently a C2-C7 alkyl group,
R₃ and R₄ are each independently hydrogen or a C1-C7 alkyl group, and
n is an integer from 0 to 3.

14. The method of claim 11, wherein the first compound is represented by Formula 1-1: 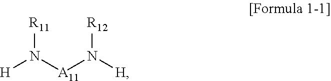
wherein, in Formula 1-1,
A₁₁ is a C1-C7 alkylene group, and
R₁₁ and R₁₂ are each independently a C3-C7 alkyl group.

15. The method of claim 11, wherein the second compound comprises at least one of 1,2-diisocyanatoethane, 1,4-diisocyanatobutane, 1,5-diisocyanatopentane, or 1,6-diisocyanatohexane.

16. The method of claim 11, further comprising:
after the forming the sacrificial layer, recessing an upper portion of the sacrificial layer.

17. The method of claim 11, wherein, in the forming the sacrificial layer, the substrate on which the sacrificial layer is formed is heated to a temperature of 50° C. to 150° C.

18. The method of claim 11, wherein, in the forming the air gap between the plurality of conductive structures, the substrate on which the capping layer is formed is heated to a temperature of 200° C. to 400° C.

19. A method of manufacturing a semiconductor device, the method comprising:
providing a first compound represented by Formula 1 and a second compound represented by Formula 2 on a substrate on which a plurality of conductive structures and a hard mask layer covering upper surfaces of the plurality of conductive structures are formed;
forming a sacrificial layer comprising polyurea between the plurality of conductive structures through a polymerization reaction of the first compound and the second compound;
recessing an upper portion of the sacrificial layer by using the hard mask layer as an etch mask;
forming a capping layer covering the upper surfaces of the plurality of conductive structures and an upper surface of the sacrificial layer; and
thermally decomposing the sacrificial layer by heating the substrate on which the capping layer is formed, wherein
in the forming the sacrificial layer, the substrate is maintained at a temperature of 50° C. to 150° C., and
in the thermally decomposing the sacrificial layer, the substrate is maintained at a temperature of 200° C. to 400° C., 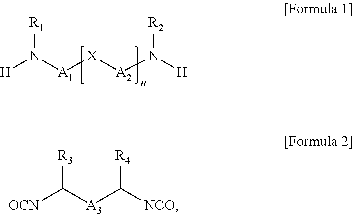
wherein, in each of Formulae 1 and 2,
A₁ and A₃ are each independently a C1-C7 alkylene group,
A₂ is a single bond or a C1-C7 alkylene group,
X is O, S, or N—R,
R is a C1-C7 alkyl group,
R₁ and R₂ are each independently a C2-C7 alkyl group,
R₃ and R₄ are each independently hydrogen or a C1-C7 alkyl group, and
n is an integer from 0 to 3.

20. The method of claim 19, wherein
the first compound comprises any one of N,N′-dimethylethylenediamine, N,N′-dimethyl-1,6-hexanediamine, N,N′-diethyl-1,6-hexanediamine, or N,N′-di-tert-butylethylenediamine.
